(19) United States
(12) Patent Application Publication
(10) Pub. No.: US 2013/0087915 A1
(43) Pub. Date: Apr. 11, 2013

(54) Copper Stud Bump Wafer Level Package

(71) Applicants: Robert W. Warren, Newport Beach, CA (US); Nic Rossi, Radio City (HK); Hyun Jung Lee, Aliso Viejo, CA (US)

(72) Inventors: Robert W. Warren, Newport Beach, CA (US); Nic Rossi, Radio City (HK); Hyun Jung Lee, Aliso Viejo, CA (US)

(73) Assignee: CONEXANT SYSTEMS, INC., NEWPORT BEACH, CA (US)

(21) Appl. No.: 13/270,012

(22) Filed: Oct. 10, 2011

(51) Int. Cl. H01L 23/498; H01L 21/66; H01L 21/56

(52) U.S. Cl. 257/738; 438/113; 438/15; 257/E23.069; 257/E21.502; 257/E21.53

(57) ABSTRACT

There is provided a system and method for a copper stud bump wafer level package. There is provided a semiconductor package comprising a semiconductor die having a plurality of bond pads on an top surface thereof, a plurality of metallic stud bumps mechanically and electrically coupled to said plurality of bond pads, and a plurality of solder balls mechanically and electrically coupled to said plurality of metallic stud bumps. Advantageously, the metallic stud bumps may be provided using standard wirebonding equipment, avoiding the conventional wafer level package requirement for photolithography and deposition steps to provide a multi-layer metallic routing structure. As a result, reduced cycle times, lower cost, and reduced complexity may be provided. Alternative fabrication processes utilizing metallic stud bumps may also support multi-die packages with dies from different wafers and packages with die perimeter pads wirebonded to substrates.

### BACKGROUND OF THE INVENTION

1. Field Of The Invention

The present invention relates generally to semiconductor device packaging. More particularly, the present invention relates to wafer level packaging.

2. Background Art

Wafer level packaging (WLP) is a technique for packaging an entire wafer of semiconductor dies at the wafer level, as compared to conventional die packaging processes that package the dies individually after wafer dicing. Since an entire wafer can be processed at one time, manufacturing throughput may be dramatically increased. Furthermore, since wafer fabrication, packaging, testing, and burn-in may be integrated at the wafer level, the device manufacturing process may be streamlined even further compared to conventional individualized die packaging. Thus, the use of WLP may be desirable to simplify, integrate, and optimize the device manufacturing process.

While there are no industry standard methods for WLP, the most common methodology extends the conventional wafer fabrication process by adding additional dielectric and metals using similar photolithography and thin film deposition techniques as for the semiconductor die itself. For example, a single or multi-layer dielectric and thin-film and plated metal structures may be provided to reroute and interconnect peripheral die bond pads of the semiconductor dies to an array of under bump metal (UBM) pads evenly distributed on the die surfaces, which in turn receive solder bumps to provide surface mountable flip chip packages.

However, significant costs are incurred to utilize such a conventional WLP process. Since additional lithography and deposition steps are required to form the metal interconnection structure, the extended use of expensive lithography and deposition equipment and processes increases costs per wafer. Moreover, the complex design of the metal interconnection structure incurs non-recurring engineering costs for each specific device. Lengthy cycle times, up to 8-10 weeks, are required for mask design and fabrication, process setup, redistribution and bumping. Thus, conventional methods of WLP undesirably increase costs, complexity, and cycle times.

Accordingly, there is a need to overcome the drawbacks and deficiencies in the art by providing a cost effective, simple, and expedited way to utilize WLP for semiconductor devices.

### SUMMARY OF THE INVENTION

There are provided systems and methods for a copper stud bump wafer level package, substantially as shown in and/or described in connection with at least one of the figures, as set forth more completely in the claims.

### BRIEF DESCRIPTION OF THE DRAWINGS

The features and advantages of the present invention will become more readily apparent to those ordinarily skilled in the art after reviewing the following detailed description and accompanying drawings, wherein:

FIG. 1A presents a top view of a copper stud bump wafer level package, according to an embodiment of the present invention;

FIG. 1B presents a cross sectional view of a wafer during wafer level packaging, according to an embodiment of the present invention;

FIG. 1C presents a cross sectional view of a wafer during wafer level packaging, according to an embodiment of the present invention;

FIG. 1D presents a cross sectional view of a wafer during wafer level packaging, according to an embodiment of the present invention;

FIG. 1E presents a cross sectional view of a wafer during wafer level packaging, according to an embodiment of the present invention;

FIG. 1F presents a cross sectional view of a wafer during wafer level packaging, according to an embodiment of the present invention;

FIG. 1G presents a cross sectional view of a wafer during wafer level packaging, according to an embodiment of the present invention;

FIG. 1H presents a cross sectional view of a copper stud bump wafer level package after singulation from a wafer, according to an embodiment of the present invention;

FIG. 2A presents a cross sectional view of a partially completed multi-die copper stud bump package, according to an embodiment of the present invention;

FIG. 2B presents a cross sectional view of a completed multi-die copper stud bump package, according to an embodiment of the present invention;

FIG. 3A presents a cross sectional view of a partially completed copper stud bump package with die perimeter pad wirebonds, according to an embodiment of the present invention;

FIG. 3B presents a cross sectional view of a completed copper stud bump package with die perimeter pad wirebonds, according to an embodiment of the present invention;

FIG. 4 shows a flowchart describing the steps, according to one embodiment of the present invention, by which a copper stud bump wafer level package may be provided.

### DETAILED DESCRIPTION OF THE INVENTION

The present application is directed to a system and method for a copper stud bump wafer level package. The following description contains specific information pertaining to the implementation of the present invention. One skilled in the art will recognize that the present invention may be implemented in a manner different from that specifically discussed in the present application. Moreover, some of the specific details of the invention are not discussed in order not to obscure the invention. The specific details not described in the present application are within the knowledge of a person of ordinary skill in the art. The drawings in the present application and their accompanying detailed description are directed to merely exemplary embodiments of the invention. To maintain brevity, other embodiments of the invention, which use the principles of the present invention, are not specifically described in the present application and are not specifically illustrated by the present drawings. Additionally, for reasons of clarity, the drawings may not be to scale.

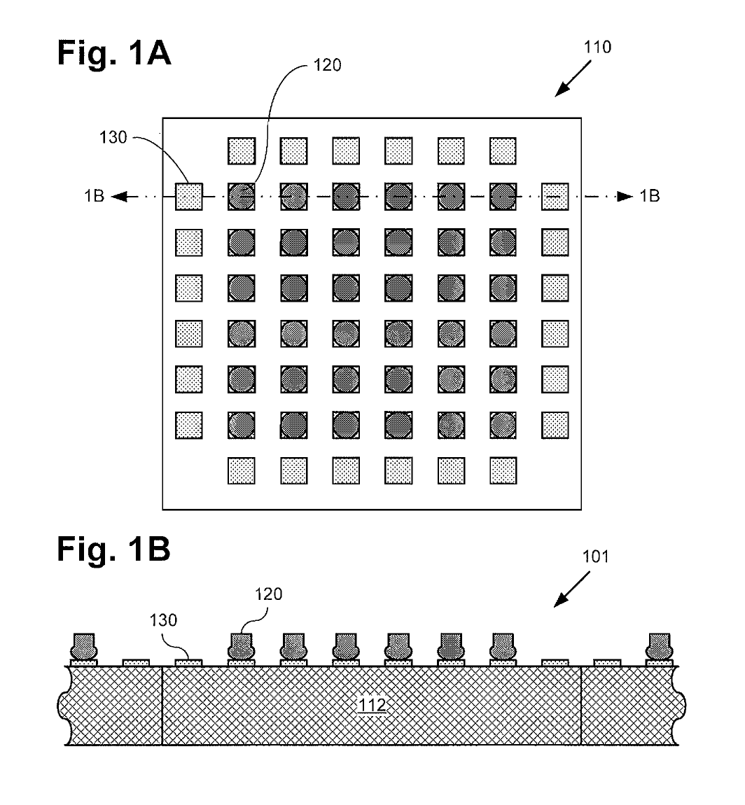

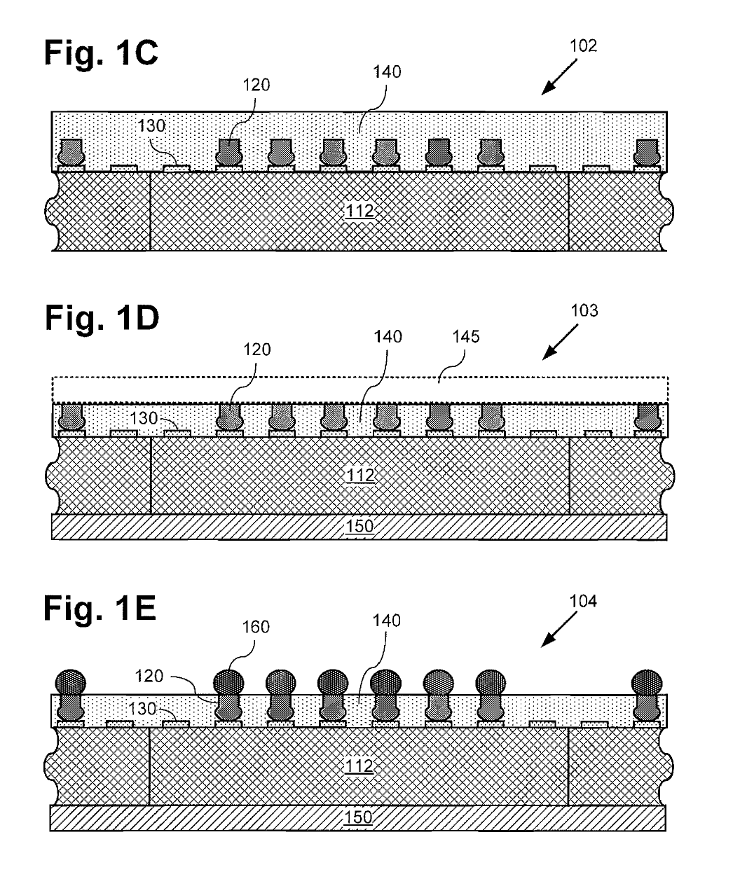

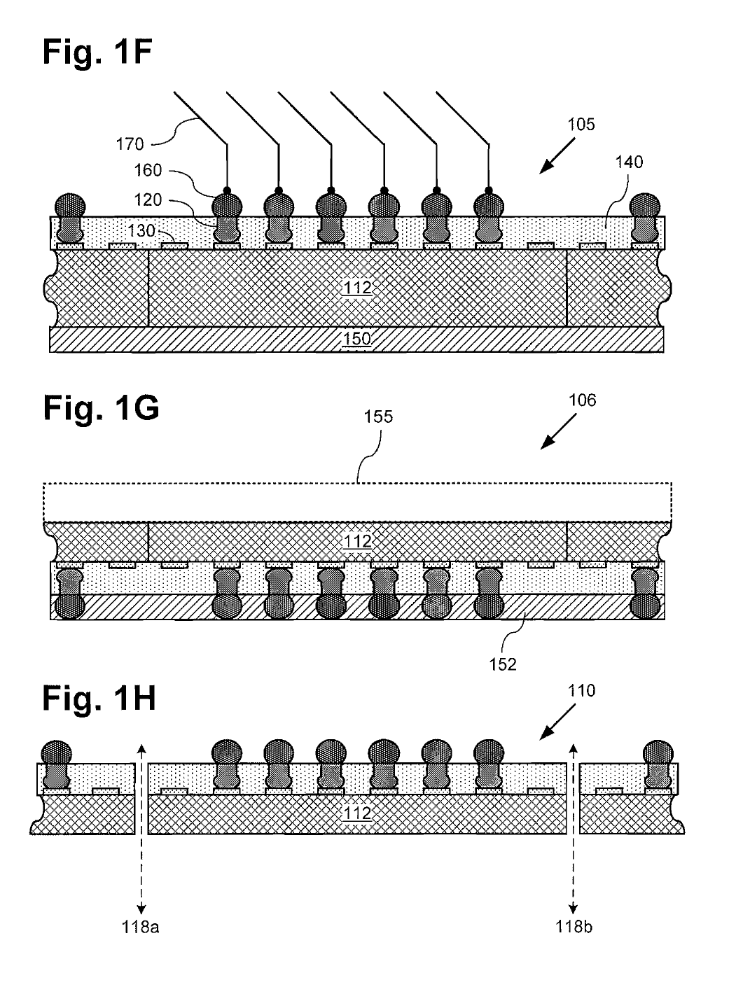

FIG. 1A presents a top view of a copper stud bump wafer level package, according to an embodiment of the present invention. Package 110 of FIG. 1A includes a plurality of copper stud bumps including stud bump 120, which are each coupled to a respective bond pad. In alternative embodiments, the plurality of stud bumps may comprise metals or metallic alloys other than copper. Package 110 may optionally include a plurality of perimeter bond pads including bond pad 130. In other embodiments, the perimeter bond pads may be removed to allow for a larger area of stud bumps. For clarity, solder bumps and mold compound have been omitted from the top view of package 110 shown in FIG. 1A.

Moving to FIG. 1B, FIG. 1B presents a cross sectional view of a wafer during wafer level packaging, according to an embodiment of the present invention. The cross section shown in FIG. 1B may correspond to cross sectional line 1B-1B from FIG. 1A, Wafer 101 of FIG. 1B may include multiple semiconductor dies arranged in a grid, including die 112 as shown. Stud bump 120 may be formed using conventional wire bonding equipment. Instead of a conventional procedure of bonding a wire between a die pad and a metal or laminate substrate, a thermosonic ball bond is formed on a die pad and the wire is terminated just above the ball bond, forming the shape of stud bump 120. Each of the die pads of die 112 may thus be mechanically and electrically coupled to a stud bump similar to stud bump 120, as shown in FIGS. 1A and 1B. Stud bumps may be omitted from perimeter bond pads such as bond pad 130, for example to reserve the perimeter bond pads for wire bonding. Advantageously, stud bump 120 may be directly bonded to a single metal finish of a die bond pad, for example an aluminum finish. In this manner, the conventional requirement for a complex multi-layer under bump metal (UBM) formulation can be avoided.

Next, FIG. 1C presents a cross sectional view of a wafer during wafer level packaging, according to an embodiment of the present invention. From FIG. 1B to FIG. 1C, a mold compound 140 encapsulates wafer 101, for example by transfer or injection molding, resulting in wafer 102. Mold compound 140 may comprise an epoxy mold compound, and may be provided by using a mold cavity or mold cap 20 to 50 microns thick, or any desired thickness. Alternatively, other encapsulant materials can be used, such as polyimide and polybenzoxazole (PBO), which may be applied by spray or spin-on techniques.

Turning to FIG. 1D, FIG. 1D presents a cross sectional view of a wafer during wafer level packaging, according to an embodiment of the present invention. From FIG. 1C to FIG. 1D, the front side of wafer 102 is mechanically grinded to remove portion 145. Prior to the grinding, a grinding tape 150 may be applied to the back side of wafer 102 for protection. Accordingly, a wafer 103 is provided wherein the plurality of stud bumps on die 112, including stud bump 120, remain encapsulated in mold compound 140 but with exposed top surfaces. Additionally, the grinding step ensures that the plurality of stud bumps provide a level top surface. In alternative embodiments, a tamping process may be utilized instead of a grinding process. For example, by depositing a thinner layer of mold compound 140 such that the plurality of stud bumps are exposed, a tamping procedure may substitute for mechanical grinding to flatten and level the exposed top surfaces of the plurality of stud bumps.

Moving to FIG. 1E, FIG. 1E presents a cross sectional view of a wafer during wafer level packaging, according to an embodiment of the present invention. From FIG. 1D to FIG. 1E, the exposed top surfaces of the stud bumps may be bumped with solder bumps or balls. For example, flux may be applied to the exposed stud bump surfaces of wafer 103 by pin transfer, solder spheres may be dropped using a step and repeat process, and the entire wafer 103 may be placed in a reflow or conveyor oven to reflow and connect the solder balls, including connecting solder ball 160 to stud bump 120. Accordingly, the solder balls may each be mechanically and electrically coupled to a respective stud bump. Thus, a wafer 104 is provided, where each of the dies including die 112 is bumped for future flip-chip, surface mount, or multi-die package integration. Advantageously, the die pads of die 112 and the other dies of wafer 104 are thus externally accessible while avoiding high cost and high complexity lithography and deposition steps as in conventional wafer level packaging.

Next, FIG. 1F presents a cross sectional view of a wafer during wafer level packaging, according to an embodiment of the present invention. As shown in FIG. 1F, wafer 105 may correspond to wafer 104 from FIG. 1E. At this point, a final wafer probe test may be conducted, where an array of cantilever probes, including probe 170, may test for the proper functionality of one or more dies at a time. Thus, an array of probes, including probe 170, may be provided for each solder ball of die 112, including solder ball 160. Multiple arrays of probes may also be utilized to test multiple dies in one pass. Additionally, if prior testing has already marked some failed dies, testing of these dies may be skipped during the final wafer probe test.

Turning to FIG. 1G, FIG. 1G presents a cross sectional view of a wafer during wafer level packaging, according to an embodiment of the present invention. From FIG. 1F to FIG. 1G, the grinding tape 150 may be removed from wafer 105. Additionally, portion 155 of wafer 105 may be optionally back grinded to result in a wafer 106 of a specific thickness. To protect wafer 105 during the grinding process, a grinding tape 152 may be applied to the front side of wafer 105, filling the space between the solder balls as shown. Thus, as shown by comparing wafer 106 of FIG. 1G with wafer 105 of FIG. 1F, the thickness of die 112 may be reduced to a desired thickness, for example 15 mils, to provide a low profile chip suitable for mobile devices.

Moving to FIG. 1H, FIG. 1H presents a cross sectional view of a copper stud bump wafer level package after singulation from a wafer, according to an embodiment of the present invention. From FIG. 1G to FIG. 1H, wafer 106 may be wafer diced using saw or laser singulation to make a grid of cuts, including cut 118a and cut 118b. Wafer 106 may also be placed on a dicing tape (not shown), which may be removed after singulation. Prior to singulation, each of the dies of wafer 106 may be laser marked on the backside to provide pin orientation, manufacturer branding, package identification, date codes, and other information. Grinding tape 152 may also be removed to provide access to the solder balls. Accordingly, completed bare dies, including package 110 as shown in FIG. 1H, may be singulated from wafer 106 of FIG. 1G. Package 110 may then be flipped and surface mounted onto a support surface such as a printed circuit board or substrate.

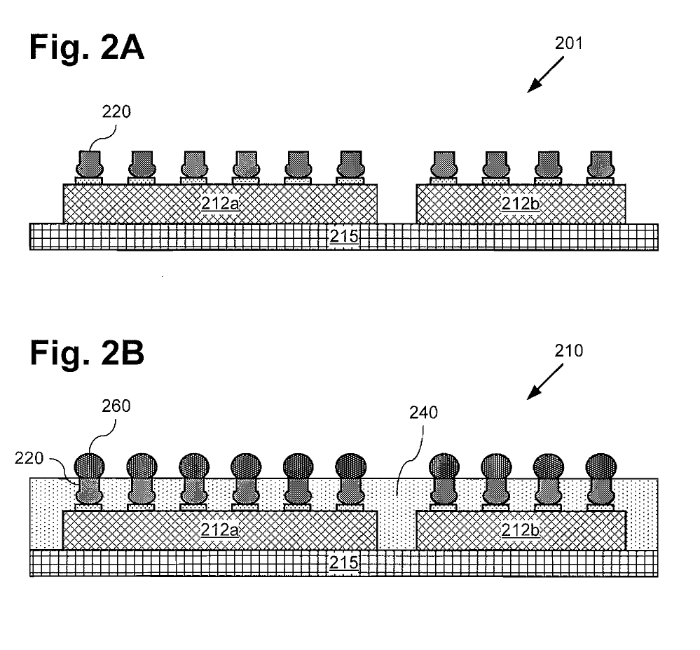

In alternative embodiments, the bare dies may be singulated and further processed and packaged individually. Thus, FIG. 2A presents a cross sectional view of a partially completed multi-die copper stud bump package, according to an embodiment of the present invention. Multi-die package 201 includes die 212a and did 212b, which both include arrays of stud bumps on their respective top surfaces, including stud bump 220 as shown. Top views of die 212a and 212b may thus appear similar to package 110 from FIG. 1A, except for omitting the optional die perimeter pads. Die 212a and 212b may be fabricated in a similar manner as die 112 from FIG. 1B, as described above. After die 212a and 212b are singulated from their respective wafers, they may be mounted to substrate 215, which may comprise a copper sheet or laminate substrate.

Next, FIG. 2B presents a cross sectional view of a completed multi-die copper stud bump package, according to an embodiment of the present invention. From FIG. 2A to FIG. 2B, the multi-die package 201 may be molded with mold compound 240, and solder balls including solder ball 260 may be deposited and connected to respective stud bumps, including stud bump 220, similar to the steps described above in FIGS. 1C, 1D, and 1E. Additionally, as previously described, the stud bumps may be tamped or grinded to ensure a level surface for receiving the solder balls.

As a result, a multi-die package 210 may be completed, which may advantageously integrate dies from different wafer technologies nodes or processes. For example, to provide a cost effective multi-function device such as a system-on-chip device, it may be desirable to provide a higher performance 32 nm process feature size for die 212a, which may comprise a central processing unit (CPU), whereas a larger and less expensive 180 nm process feature size may be provided for die 212b, which may comprise a system I/O or graphics processor. Different wafer technologies and processes can also be integrated into one multi-die package, such as BiCMOS and RFCMOS.

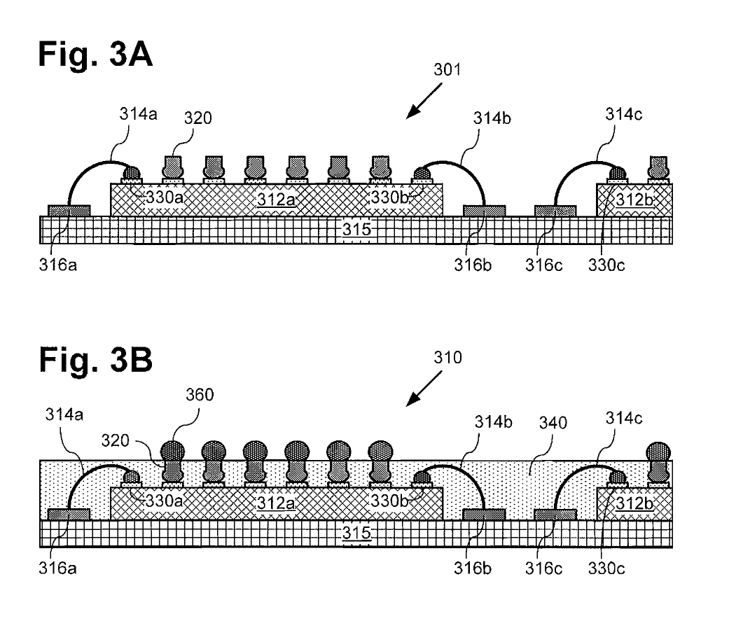

In another embodiment, die perimeter pads may also be utilized for routing to a package substrate. Thus, FIG. 3A presents a cross sectional view of a partially completed copper stud bump package with die perimeter pad wirebonds, according to an embodiment of the present invention. Package 301 of FIG. 3A includes die 312 mounted on substrate 315. Die 312a may correspond to die 112 from FIG. 1B, and substrate 315 may correspond to substrate 215 from FIG. 2A. Substrate 315 includes bond pad 316a, 316b and 316c on a top surface thereof. Die 312a includes a plurality of die pads on a top surface thereof, which in turn receive a plurality of stud bumps including stud bump 320. Die 312a also includes a plurality of die perimeter pads on a top surface thereof, including die perimeter pad 330a and die perimeter pad 330b. Adjacent to die 312a, an additional die 312b may be mounted on substrate 315. Die 312b may be similar in structure to die 312a, and may thus include a plurality of die pads on a top surface thereof, which in turn receive a plurality of stud bumps. Die 312b also includes a plurality of die perimeter pads on a top surface thereof, including die perimeter pad 330c. For simplicity, only a portion of die 312b may be shown.

Wire 314a, 314b and 314c are provided for substrate routing and may comprise, for example, copper wire. Prior to wire bonding of wire 314a, 314b and 314c, a top view of die 312a may appear similar to the top view of package 110 in FIG. 1A, including the optional die perimeter pads. After wire bonding, wire 314a may connect die perimeter pad 330a to bond pad 316a, wire 314b may connect die perimeter pad 330b to bond pad 316b, and wire 314c may connect die perimeter pad 330c to bond pad 316c. Thus, the die perimeter pads of die 312a including die perimeter pad 330a and 330b may be routed through substrate 315 and connected to one or more adjacent dies. For example, bond pad 316b and 316c may be connected through substrate 315, thereby connecting die 312a to die 312b. Advantageously, the stud bumps, including stud bump 320, and the wire bonds, including wire 314a, 314b and 314c, may both be applied in one pass, as both features may be formed using the same wire bonding equipment.

Continuing, FIG. 3B presents a cross sectional view of a completed copper stud bump package with die perimeter pad wirebonds, according to an embodiment of the present invention. From FIG. 3A to FIG. 3B, package 301 may be encapsulated in mold compound 340, and solder balls including solder ball 360 may be deposited and connected to respective stud bumps, including stud bump 320, similar to the steps described above in FIGS. 1C, 1D, and 1E. Additionally, as previously described, the stud bumps may be tamped or grinded to ensure a level surface for receiving the solder balls.

As a result, a package 310 may be completed, which may flexibly distribute the die pads of die 312 through both substrate 315 and through solder balls exposed on an opposite surface. Accordingly, lateral multi-die configurations, stacked die configurations and other vertical arrangements may be readily supported.

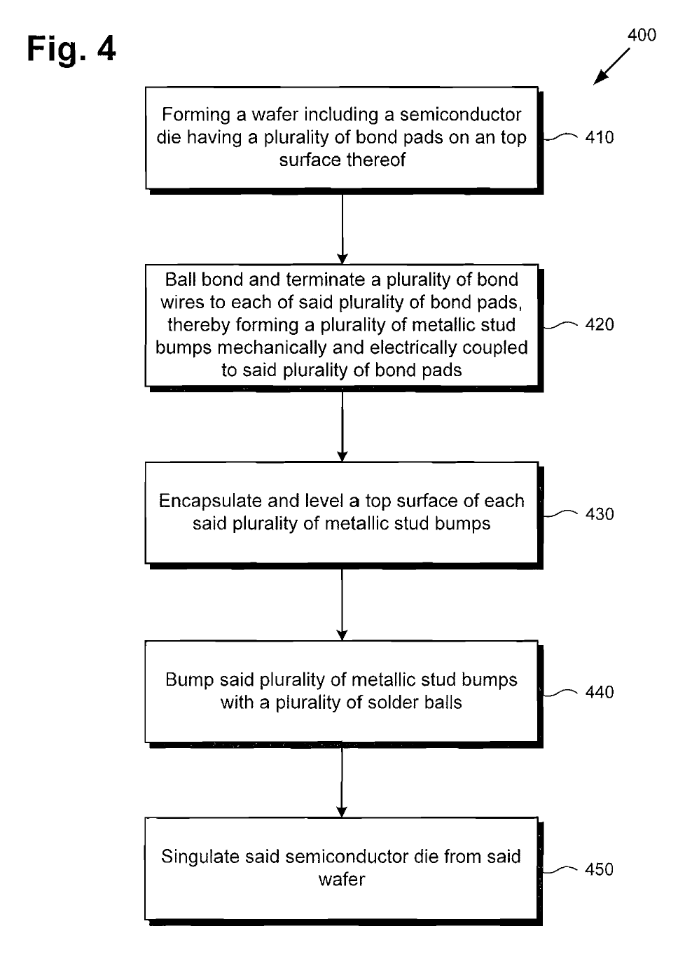

FIG. 4 shows a flowchart describing the steps, according to one embodiment of the present invention, by which a copper stud bump wafer level package may be provided. Certain details and features have been left out of flowchart 400 that are apparent to a person of ordinary skill in the art. For example, a step may comprise one or more substeps or may involve specialized equipment or materials, as known in the art. While steps 410 through 450 indicated in flowchart 400 are sufficient to describe one embodiment of the present invention, other embodiments of the invention may utilize steps different from those shown in flowchart 400.

Referring to step 410 of flowchart 400 in FIG. 4 and wafer 101 of FIG. 1B, step 410 of flowchart 400 comprises forming wafer 101 including die 112 having a plurality of bond pads on a top surface thereof. The forming of wafer 101 may utilize conventional wafer fabrication techniques as known in the art. A top view of die 112 may appear similar to the top view of package 110 in FIG. 1A, where an evenly spaced grid of bond pads receive stud bumps such as stud bump 120. Optionally, die perimeter pads such as die perimeter pad 130 may also be provided on the top surface of die 112.

Referring to step 420 of flowchart 400 in FIG. 4 and wafer 101 of FIG. 1B, step 420 of flowchart 400 comprises ball bonding and terminating a plurality of bond wires to each of the plurality of bond pads formed in step 410, thereby forming a plurality of metallic stud bumps, including stud bump 120, which are mechanically and electrically coupled to the plurality of bond pads. The wires forming the stud bumps may comprise any number of metals or metallic alloys, for example copper. Accordingly, step 420 may be advantageously carried out using standard wirebonding equipment, avoiding the complexity and cost of conventional wafer level packaging processes that utilize lithography and deposition to provide a multi-layer routing structure.

Referring to step 430 of flowchart 400 in FIG. 4, wafer 102 of FIG. 1C, and wafer 103 of FIG. 1D, step 430 of flowchart 400 comprises encapsulating and leveling a top surface of each of the plurality of metallic stud bumps formed in step 420. For example, by encapsulating a mold compound 140 around wafer 101 of FIG. 1B, resulting in wafer 102 of FIG. 1C, and by front grinding portion 145 of wafer 102, resulting in wafer 103 of FIG. 1D, the top surfaces of the stud bumps may be leveled, including stud bump 120. Alternatively, a thinner layer of mold compound 140 may be provided such that the stud bumps may be tamped down instead of grinded.

Referring to step 440 of flowchart 400 in FIG. 4 and wafer 104 of FIG. 1E, step 440 of flowchart 400 comprises bumping the plurality of metallic stud bumps leveled from step 430 with a plurality of solder balls. Thus, as shown by wafer 104, each of the stud bumps of die 112 is bumped with a corresponding solder ball, including stud bump 120 being bumped with solder ball 160. Accordingly, the connections of die 112 are made accessible for flip chip or surface mounting.

Referring to step 450 of flowchart 400 in FIG. 4 and package 110 of FIG. 1H, step 450 of flowchart 400 comprises singulating package 110 from the wafer. For example, the wafer may be diced using saw or laser singulation to make a grid of cuts, including cut 118a and cut 118b. Prior to singulation, various optional steps may be carried out including wafer probe testing as illustrated in FIG. 1F, back side wafer thinning as illustrated in FIG. 1G, and laser marking to provide package identification information.

Thus, a method for providing a copper stud bump wafer level package has been disclosed. By utilizing standard wirebonding equipment to provide copper stud bumps to route semiconductor die connections in a wafer level packaging process, the conventional requirement for lithography and deposition steps to provide a metal interconnection structure may be advantageously avoided, reducing fabrication costs. Complexity may also be reduced as an under bump metal (UBM) formulation may be omitted and a substrate is no longer necessary. Further, by avoiding the design and fabrication requirement for the metal interconnection structure used in conventional wafer level packaging, a fast cycle time may be provided, providing engineering wafers in days rather than in weeks. This quick turnaround may be especially useful for rapid device prototyping, as several different device revisions may be fabricated on a single wafer and quickly tested. Additionally, as illustrated in FIGS. 2A-2B and 3A-3B respectively, the copper stud bump concept may also be applied to provide multi-die packages or to provide packages interconnecting die perimeter pads to a substrate.

From the above description of the invention it is manifest that various techniques can be used for implementing the concepts of the present invention without departing from its scope. Moreover, while the invention has been described with specific reference to certain embodiments, a person of ordinary skills in the art would recognize that changes can be made in form and detail without departing from the spirit and the scope of the invention. As such, the described embodiments are to be considered in all respects as illustrative and not restrictive. It should also be understood that the invention is not limited to the particular embodiments described herein, but is capable of many rearrangements, modifications, and substitutions without departing from the scope of the invention.

What is claimed is:

1. A semiconductor package comprising:
a semiconductor die having a plurality of bond pads on an top surface thereof;
a plurality of metallic stud bumps mechanically and electrically coupled to said plurality of bond pads;
a plurality of solder balls mechanically and electrically coupled to said plurality of metallic stud bumps.

2. The semiconductor package of claim 1, wherein said plurality of metallic stud bumps is a plurality of copper stud bumps.

3. The semiconductor package of claim 1, further comprising a mold compound encapsulating said plurality of metallic stud bumps while exposing a top surface of each of said plurality of metallic stud bumps.

4. The semiconductor package of claim 1, wherein said plurality of bond pads include a single metal finish.

5. The semiconductor package of claim 4, wherein said single metal finish is an aluminum finish.

6. The semiconductor package of claim 1, wherein said semiconductor die is mounted on a substrate.

7. The semiconductor package of claim 6, wherein said semiconductor die further includes a plurality of die perimeter pads on said top surface thereof, said plurality of die perimeter pads connecting to said substrate by a plurality of wire bonds.

8. The semiconductor package of claim 7, wherein said plurality of wire bonds is a plurality of copper wire bonds.

9. The semiconductor package of claim 6, wherein another semiconductor die is mounted on said substrate, said another semiconductor die having a plurality of bond pads on an top surface thereof, said another semiconductor die having a plurality of metallic stud bumps mechanically and electrically coupled to said plurality of bond pads, said another semiconductor die having and a plurality of solder balls mechanically and electrically coupled to said plurality of metallic stud bumps.

10. The semiconductor package of claim 9, wherein a process feature size of said semiconductor die is different from a process feature size of said another semiconductor die.

11. A method for fabricating a semiconductor package comprising:
forming a wafer including a semiconductor die having a plurality of bond pads on an top surface thereof;
ball bonding and terminating a plurality of bond wires to each of said plurality of bond pads, thereby forming a plurality of metallic stud bumps mechanically and electrically coupled to said plurality of bond pads;
leveling a top surface of each said plurality of metallic stud bumps;
bumping said plurality of metallic stud bumps with a plurality of solder balls;
singulating said semiconductor die from said wafer.

12. The method of claim 11, wherein after said forming said wafer and prior to said singulating, no photolithography or deposition equipment is utilized.

13. The method of claim 11 further comprising, prior to said leveling:
applying a grinding tape to a backside of said wafer.

14. The method of claim 11, wherein said leveling comprises:
encapsulating a mold compound around said wafer including said plurality of metallic stud bumps;
grinding said mold compound to expose a top surface of each of said plurality of metallic stud bumps through said mold compound.

15. The method of claim 11, wherein said leveling comprises:
encapsulating a mold compound around said wafer including said plurality of metallic stud bumps while exposing a top surface of each of said plurality of metallic stud bumps;
tamping said plurality of metallic stud bumps.

16. The method of claim 11 further comprising, prior to said singulating, verifying a proper functionality of said semiconductor die by a wafer probe test applied to said plurality of solder balls.

17. The method of claim 11 further comprising, prior to said singulating, laser marking said semiconductor die.

18. The method of claim 11 further comprising, prior to said singulating, back grinding said semiconductor die to a specific thickness.

19. The method of claim 11 wherein said plurality of metallic stud bumps is a plurality of copper stud bumps.

20. The method of claim 11 wherein said plurality of bond pads include a single metal finish.
